(19) United States
(12) Patent Application Publication
(10) Pub. No.: US 2008/0186627 A1
(43) Pub. Date: Aug. 7, 2008

(54) PERPENDICULAR MAGNETIC RECORDING MEDIUM WITH GRANULAR STRUCTURED MAGNETIC RECORDING LAYER, METHOD FOR PRODUCING THE SAME, AND MAGNETIC RECORDING APPARATUS

(75) Inventors: Yoshiyuki Hirayama, Tokyo (JP); Ikuko Takekuma, Kanagawa (JP); Ichiro Tamai, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global Storage Technologies Netherlands B. V., Amsterdam (NL)

(21) Appl. No.: 12/061,518

(22) Filed: Apr. 2, 2008

Related U.S. Application Data
(63) Continuation of application No. 11/258,532, filed on Oct. 24, 2005.

(30) Foreign Application Priority Data
Oct. 25, 2004 (JP) 2004-309848

(51) Int. Cl. G11B 5/33; G11B 5/66; C23C 14/34

(52) U.S. Cl. 360/110; 428/828; 204/192.12

(57) ABSTRACT

Embodiments of the invention provide a perpendicular magnetic recording medium having a granular structured magnetic recording layer including many columnar grains, and grain boundary layers containing oxide, wherein a high medium S/N ratio is obtained while securing head flyability and durability. In an embodiment, the perpendicular magnetic recording medium includes a granular structured magnetic recording layer having many columnar grains, as well as grain boundary layers including oxide respectively. Assuming that the columnar grains are divided equally in the film thickness direction into a protective layer side portion and an intermediate layer side portion, and the diameter of the protective layer side portion is larger than that of the intermediate layer side portion.

### CROSS-REFERENCES TO RELATED APPLICATIONS

This application claims priority from Japanese Patent Application No. JP2004-309848, filed Oct. 25, 2004, the entire disclosure of which is incorporated herein by reference.

### BACKGROUND OF THE INVENTION

The present invention relates to magnetic recording media capable of recording mass information, a method for manufacturing the same, and a magnetic recording/reproducing apparatus, more particularly to magnetic recording media for high density magnetic recording, a method for manufacturing the same, and a magnetic recording/reproducing apparatus.

Compact and large capacity magnetic disk drives have come to be widely employed not only for personal computers, but also for home electric appliances. Under such circumstances, supply of larger capacity magnetic storage devices has been strongly demanded, so that improvement of the recording density has been required. In order to meet these requirements, magnetic heads, magnetic recording media, etc. are now under development energetically. Actually, however, it is difficult to improve the recording density with the longitudinal magnetic recording method that is already put to practical use. This is why the perpendicular magnetic recording method is being examined to determine whether it is employable instead of the longitudinal magnetic recording method. In case of the perpendicular magnetic recording method, adjacent magnetizing directions are always opposed from each other and this is why the high density recording state is stabilized, and hence the method is considered to be suitable for high density recording. In addition, the method enables double layered perpendicular magnetic recording media to be combined to thereby improve the recording efficiency so as to cope with an increase of the coercivity of the recording film. Each of the double layered perpendicular magnetic recording media includes a single pole type recording head and a soft-magnetic underlayer. If the perpendicular magnetic recording method is used to improve the high density recording, it is necessary to improve the requirements of low noise and strong resistance to thermal decay.

A Co—Cr—Pt-alloy film that is already put to practical use in the longitudinal magnetic recording media has been examined as the recording layer of the perpendicular magnetic recording media. However, if the Co—Cr—Pt-alloy film is used to obtain the low noise characteristic, it is necessary to reduce the magnetic reversal unit by lowering the exchange coupling between magnetic crystal grains by use of the Cr segregation to the crystal grain boundary. If the Cr is insufficient in amount; however, grains come to be combined to become fat or the exchange coupling between grains is not lowered sufficiently, and hence the low noise characteristic is not obtained. On the other hand, if the Cr increases in amount, much Cr comes to stay in grains, whereby the magnetic anisotropy energy of the magnetic grains goes down. The resistance to thermal decay thus becomes insufficient.

In order to solve such problems to obtain the low noise characteristic, examinations have come to be done widely for the granular type recording layer obtained by adding oxygen or oxide to the Co—Cr—Pt-alloy. If this granular type recording layer is to be used, an oxide grain boundary layer is formed so as to enclose each magnetic grain to lower the exchange coupling between magnetic grains. This is why a material having high magnetic anisotropy energy can be used as the Co—Cr—Pt-alloy regardless of the Cr concentration. Because the oxide grain boundary layer is discontinuous to its magnetic grain in the viewpoint of the crystal and has a certain thickness, grains are hardly combined with each other in the recording layer forming process. Consequently, if the grain boundary layer is formed of oxide successfully, the perpendicular magnetic recording medium can realize the requirements of low noise and strong resistance to thermal decay.

For example, the official gazette of JP-A No. 178413/2003 discloses such a perpendicular magnetic recording medium in which the cubic volume of each non-magnetic grain boundary made mainly of oxide accounts for 15% to 40% of that of the whole magnetic layer. The official gazette also describes the importance to control the amount of oxide contained in the magnetic layer properly to secure the low noise characteristic by controlling the segregation structure of the granular type magnetic layer.

As a result of examinations from various viewpoints of the granular type perpendicular magnetic recording media, there have arisen some problems specific to the granular type media. As described above, it is important to control the amount of oxide contained in the magnetic layer. However, the following problems are found to arise from such a controlling method. Concretely, if the amount of oxide is insufficient, the oxide to form grain boundary layers is also insufficient, whereby the exchange coupling between magnetic grains cannot be lowered enough and noise cannot be suppressed. On the other hand, if the amount of oxide is sufficient, oxide comes to exist outside the grain boundary layers as well and this comes to cause grains to be divided more minutely than expected in the recording layer forming process, so that the resistance to thermal decay is lowered. In such a case, even if the amount of oxide is optimized at a place, the amount of oxide comes to be insufficient or excessive in other places. This is because the oxide segregation structure is varied among places. It is very difficult to optimize the amount of oxide all over the area of the subject disk.

Furthermore, even if the amount of oxide could be optimized in many places, the shapes of magnetic grains are tapered, so that both of the durability and the head flyability are disadvantageously lowered. Such tapered shapes of grains in the magnetic recording layer from the intermediate layer toward the protective layer are often recognized characteristically in the granular type magnetic recording layer. Particularly, the phenomenon appears remarkably when the exchange coupling between magnetic grains is lowered enough due to an increase in the amount of oxide and to the grains reduced in diameter. If the grains are tapered in shape, it comes to cause various problems in addition to the problems of degradation to occur in both durability and head flyability. For example, the protective layer needs to be formed thick to obtain the sufficient corrosion resistance, since the protective layer is insufficient in covering the surface of the magnetic layer completely.

### BRIEF SUMMARY OF THE INVENTION

In the perpendicular magnetic recording medium having a granular-structured magnetic recording layer composed of many columnar grains and grain boundary layers including oxide, the medium noise can be reduced effectively by increasing addition of oxide that forms the grain boundary layers of the magnetic recording layer, thereby lowering the exchange coupling between magnetic grains or by reducing the magnetic grains in diameter, thereby lowering the magnetic reversal unit. If such means is employed, however, the grains in the shape of the magnetic recording layer are tapered from the intermediate layer to the protective layer, whereby both head flyability and durability of the medium are degraded, and the corrosion resistance is lowered. In addition, the reproduced output goes down more than expected, so that the media S/N ratio is not improved so much. On the other hand, if the addition of oxide to the magnetic recording layer is suppressed to secure both head flyability and durability of the medium, tapering of the shape of the grains in the magnetic recording layer is prevented and the grains will grow almost in the same diameter. Even in such a case, the significantly lowered media S/N ratio cannot be avoided, however.

Under such circumstances, it is a feature of the present invention to realize a high media S/N ratio while both head flyability and durability are secured in a perpendicular magnetic recording medium having a granular-structured magnetic recording layer.

The present invention is mainly characterized by having a perpendicular magnetic recording medium having at least a soft-magnetic underlayer, an intermediate layer, a magnetic recording layer, and a protective layer, those layers being laminated in this order on a substrate. The magnetic recording layer is of granular-structure that is composed of many columnar grains and grain boundary layers including oxide; and the columnar grains have a shape in which a protective layer side portion is larger in diameter than an intermediate layer side portion, assuming that the columnar grains are divided equally into two portions, i.e., the protective layer side portion and the intermediate layer side portion, in their film thickness direction.

In some embodiments, the perpendicular magnetic recording medium is characterized in that the magnetic recording layer is formed such that the oxygen content of the protective layer side portion is lower than that of the intermediate layer side portion.

To improve both head flyability and durability of the perpendicular magnetic recording medium having a granular-structured magnetic recording layer, there is a method to suppress the addition of oxide to the magnetic recording layer, reduce the grain boundaries in width, and increase the grains in diameter. The magnetic recording layer the whole of which is formed in such a way as to unavoidably cause the medium S/N ratio to be lowered. To cope with this, the present inventors made a finding that suppression of the oxygen content of the columnar grains only in protective layer side portion in the magnetic recording layer significantly contributes to the improvement of the head flyability and the durability. The present inventors also found that increasing the oxygen content of the columnar grains in the intermediate layer side portion causes no problem in the head flyability, and, on the contrary, the medium S/N ratio is improved more than the media having the conventional structure. Note that the medium S/N ratio is lowered if the grains in the magnetic recording layer are cut into more fine pieces or the grains in the intermediate layer side portion are excessively fined, and each grain in the magnetic recording layer is not formed as a continuous columnar shape between the boundaries of the intermediate layer and of the protective layer. The present inventors further found that both requirements of the head flyability and the medium S/N ratio are satisfied if the oxygen content is distributed in the magnetic recording layer such that the oxygen content in the protective layer side portion is lower than that in the intermediate layer side portion, and the diameter of the columnar grains in the protective layer side portion is larger than that of the columnar grains in the intermediate layer side portion. According to the present invention, therefore, the oxygen content in the protective layer side portion of the magnetic recording layer may be set low, so that the allowable range of the oxide addition is widened. Accordingly, the required properties of the magnetic recording layer are thus satisfied all over the area of the subject disk.

In order to realize such properties of the magnetic recording layer of the present invention effectively, the intermediate layer should have plural layers and one of the plural intermediate layers, which is located immediately beneath the magnetic recording layer, should be a granular-structured one composed of many grains and grain boundary layers including oxide while the columnar grains contained in the magnetic recording layer should be larger in diameter than the grains contained in the intermediate layer located immediately beneath the magnetic recording layer or the oxygen content of the magnetic recording layer should be lower than that of the intermediate layer located immediately beneath the magnetic recording layer. In that connection, the intermediate layer located immediately beneath the magnetic recording layer should preferably be made of Ru or an Ru alloy and the grains contained in the intermediate layer located immediately beneath the magnetic recording layer should be about 5 nm to 8 nm in diameter so as to achieve the object effectively. According to the present invention, the oxygen content of the magnetic recording layer may be low, so that the allowable range of the oxide addition can be set widely. It is thus easy to realize the properties favorably all over the area of the subject disk.

According to the present invention, the method for manufacturing the perpendicular magnetic recording medium is mainly characterized in that the magnetic recording layer is formed under a sputtering process having at least two consecutive steps, and that the power supply in the sputtering in the first step is smaller than that in the sputtering in the second step or the oxygen gas flow rate in the first step is lower than that in the second step. The sputtering process for such a magnetic recording layer is not required to use plural sputtering target materials; one and the same material may be used in the same process chamber. Consequently, the process can be executed consecutively non-stop in plural steps, so that the shape of the columnar grains in the magnetic recording layer can be controlled. In other words, while the shape of each of the columnar grains is continued between the boundaries of the intermediate layer and of the protective layer, only the diameter of the columnar grains can be changed.

The perpendicular magnetic recording medium of the present invention has a granular-structured magnetic recording layer having many columnar grains and grain boundary layers including oxide. The columnar grains are larger in diameter in the protective layer side portion than those in the intermediate layer side portion. The surface of the medium can be smoothed to improve both head flyability and durability or corrosion resistance of the medium. Furthermore, the reproduced output, etc. can also be increased to improve the medium S/N ratio. There is no need to further reduce the columnar grains in diameter in the magnetic recording layer to improve the medium S/N ratio, so that the resistance to thermal decay is secured.

### BRIEF DESCRIPTION OF THE DRAWINGS

FIG. 1 is an explanatory image of a cross-sectional structure of a perpendicular magnetic recording medium sample 1, which is observed under a transmission electron microscope in the first embodiment of the present invention;

FIG. 2 is an explanatory image of a layer configuration of the perpendicular magnetic recording medium sample 1 in the embodiment of the present invention;

FIG. 3 is a chamber configuration of a manufacturing apparatus of the perpendicular magnetic recording medium sample 1 in the first embodiment of the present invention;

FIG. 4 is a flowchart of a manufacturing method of the perpendicular magnetic recording medium in the first embodiment of the present invention;

FIG. 5 is a graph for describing a relationship between the medium S/N ratio and the grain diameter ratio D2/D1 in the perpendicular magnetic recording medium in the first embodiment of the present invention;

FIG. 6 is a graph for describing a relationship between the output decay rate and the grain diameter ratio D2/D1 in the perpendicular magnetic recording medium in the first embodiment of the present invention;

FIG. 7 is a graph for describing a relationship between the glide head average output and the grain diameter ratio D2/D1 in the perpendicular magnetic recording medium in the first embodiment of the present invention;

FIG. 8 shows a graph for describing the distribution of each element content in the depth direction with use of an x-ray photoelectron spectroscopy in the perpendicular magnetic recording medium sample 1 in the first embodiment of the present invention;

FIG. 9 shows a graph for describing the distribution of each element content in the depth direction with use of an x-ray photoelectron spectroscopy in the perpendicular magnetic recording medium sample 10 in the first embodiment of the present invention;

FIG. 10 is a graph for describing a relationship between the medium S/N ratio and the oxygen content ratio C2/C1 in the perpendicular magnetic recording medium in the first embodiment of the present invention;

FIG. 11 is a flowchart of how to manufacture a perpendicular magnetic recording medium in the second embodiment of the present invention;

FIG. 12 is a graph for describing a relationship between the medium S/N ratio and the grain diameter ratio D2/D1 in the perpendicular magnetic recording medium in the second embodiment of the present invention;

FIG. 13 is a graph for describing a relationship between the output decay rate and the grain diameter ratio D2/D1 in the perpendicular magnetic recording medium in the second embodiment of the present invention;

FIG. 14 is a graph for describing a relationship between the glide head average output and the grain diameter ratio D2/D1 in the perpendicular magnetic recording medium in the second embodiment of the present invention;

FIG. 15 is an explanatory image of a cross-sectional structure of a perpendicular magnetic recording medium sample 30 under a transmission electron microscope in the third embodiment of the present invention;

FIG. 16 is a graph for describing a relationship between the medium S/N ratio and the grain diameter ratio D_CCP/D_Ru in the perpendicular magnetic recording medium in the third embodiment of the present invention;

FIG. 17 is a graph for describing a relationship between the glide head average output and the grain diameter ratio D_CCP/D_Ru in the perpendicular magnetic recording medium in the third embodiment of the present invention;

FIG. 18 shows a graph for describing the distribution of each element content in the depth direction with use of an x-ray photoelectron spectroscopy in a perpendicular magnetic recording medium sample 30 in the third embodiment of the present invention;

FIG. 19 shows a graph for describing the distribution of each element content in a depth with use of an x-ray photoelectron spectroscopy in a perpendicular magnetic recording medium sample 33 in the third embodiment of the present invention;

FIG. 20 is a graph for describing a relationship between the medium S/N ratio and the oxygen content ratio C_CCP/C_Ru in the perpendicular magnetic recording medium in the third embodiment of the present invention;

FIG. 21 is a graph for describing a relationship between the medium S/N ratio and the Ru layer grain diameter in the perpendicular magnetic recording medium in the embodiment of the present invention;

FIG. 22 illustrates a magnetic recording/reproducing apparatus.

### DETAILED DESCRIPTION OF THE INVENTION

### First Embodiment

FIG. 2 shows an explanatory cross sectional view of a perpendicular magnetic recording medium according to an embodiment of the present invention. This perpendicular magnetic recording medium is structured to have a pre-coating layer 21, a soft magnetic layer 22, a seed layer 23, an intermediate layer 24, a magnetic recording layer 25, and a protective layer 26 that are laminated in this order on a substrate 20.

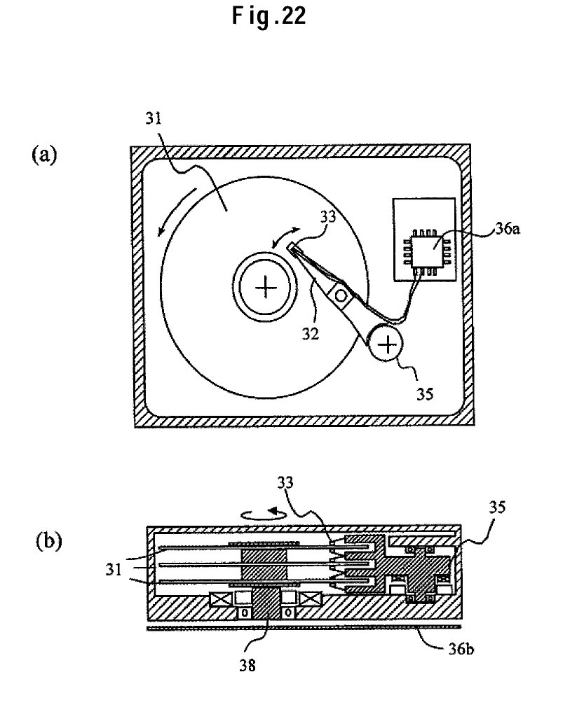

FIG. 22 shows a concept chart of a magnetic recording/reproducing apparatus according to an embodiment of the present invention. This magnetic recording/reproducing apparatus writes/reads magnetization signals, with use of magnetic heads of sliders 33 fixed to the tip of a suspension arm 32, in/from a desired positions on magnetic disks (perpendicular magnetic recording media) 31 driven rotationally by a motor 38. A rotary actuator 35 is driven to allow the magnetic heads to make access to a desired position (track) in the radial direction of the magnetic disks. Signals written/read by use of the magnetic heads are processed in signal processing circuits 36a and 36b. The magnetic heads are read/write composite heads provided with a recording head having a main pole and a return pole, as well as a reading head including a reading device having a giant magneto-resistive effect device (GMR), a tunneling magneto-resistive effect device (TMR), etc.

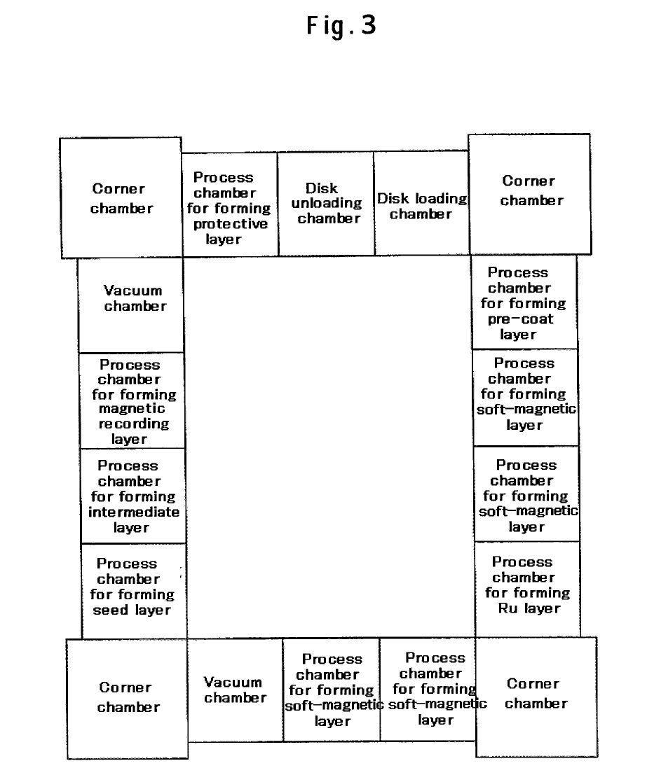

The perpendicular magnetic recording medium in this first embodiment is manufactured with use of a sputtering apparatus (C-3010) manufactured by ANELVA Corporation. FIG. 3 shows how to arrange the chambers of the sputtering apparatus. This sputtering apparatus comprises 10 process chambers, a disk loading chamber, and a disk unloading chamber. Each of those chambers is evacuated independently. After every chamber is evacuated down to a vacuum degree of 1×10⁻⁵ Pa and below, a disk-loaded carrier is moved into each process chamber to be subjected to the corresponding treatment.

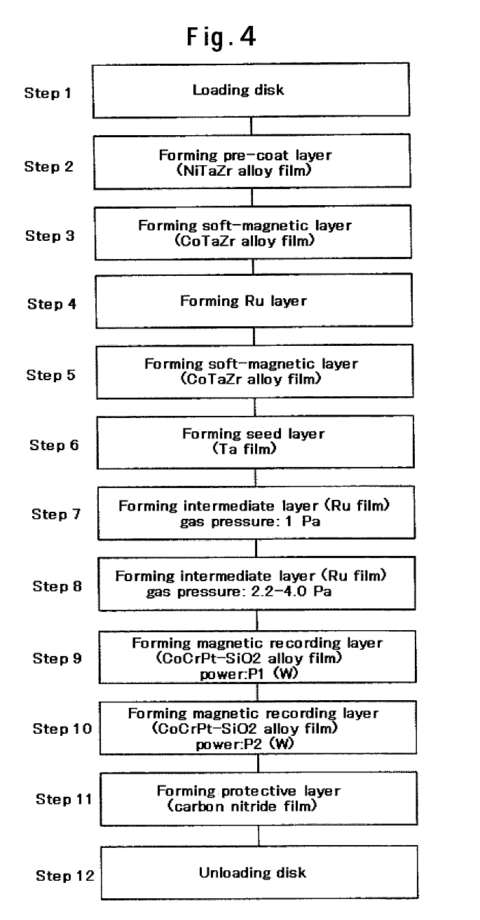

FIG. 4 shows a flowchart of the manufacturing method, in which, a pre-coat layer 21, a soft-magnetic layer 22, a seed layer 23, an intermediate layer 24, a magnetic recording layer 25, and a protective layer 26 are laminated in this order on a substrate 20. The substrate 20 is a glass substrate having a thickness of 0.635 mm and a diameter of 65 mm. The pre-coat layer 21 is a Ni base alloy film with 37.5 at % Ta and 10 at % Zr having a thickness of 30 nm. The soft-magnetic layer 22 is a laminated film having two Co base alloy films with 8 at % Ta and 5 at % Zr having a thickness of 50 nm with an Ru film having a thickness of 0.5 nm therebetween. The seed layer 23 is a Ta film having a thickness of 1 nm and the intermediate layer 24 is an Ru film having a thickness of 10 nm. Argon sputtering gas is used in those processes. The Ru film is formed by sequentially laminating a film formed by sputtering at a gas pressure of 1 Pa and a film formed by sputtering at a gas pressure of 2.2 Pa to 4.0 Pa, and by changing the film thickness ratio between those two Ru films and the gas pressure used to form the second Ru film to thereby change the size of the Ru grains.

The magnetic recording layer 25 is formed by sputtering with use of a target obtained by adding 7 mol % of Silicon oxide to a Co base alloy with 15 at % Cr and 18 at % Pt in argon and oxygen mixed gas, where the gas pressure is 2.2 Pa and the oxygen partial pressure is 0.02 Pa. During the process, the power supply is changed continuously so as to change the fine structure of the magnetic recording layer. The power supplied in the first half of the process is defined as P1 (W) and the power supplied in the second half is defined as P2 (W). Table 1 shows each sample forming condition. The process time is adjusted so that the magnetic recording layer has a thickness of 14 nm. The protective layer 26 is formed by sputtering, with use of a carbon target, in argon and nitrogen mixed gas, where the argon gas pressure is 0.6 Pa and the nitrogen gas pressure is 0.05 Pa. The nitrogen carbon film is 4 nm in thickness. A lubricant film is formed on the surface of the protective layer for each sample evaluated by flying the head.

TABLE 1

| | | | Ru Layer | | | |
|---|---|---|---|---|---|---|
| | Magnetic | | Grain | Magnetic Recording | | |
| | Recording | | Diameter | Layer Grain | | |
| Sample | Layer Process | | D_Ru | Diameter | | |
| No. | P1 (W) | P2 (W) | (nm) | D1 (nm) | D2 (nm) | D2/D1 |
| 1 | 260 | 520 | 8.2 | 7.0 | 7.4 | 1.06 |
| 2 | 260 | 520 | 6.8 | 5.7 | 6.1 | 1.07 |
| 3 | 260 | 520 | 5.7 | 4.7 | 5.1 | 1.09 |
| 4 | 260 | 260 | 8.1 | 7.4 | 7.3 | 0.98 |
| 5 | 260 | 260 | 6.9 | 6.3 | 6.2 | 0.98 |
| 6 | 260 | 260 | 5.6 | 5.1 | 4.9 | 0.96 |
| 7 | 390 | 390 | 8.2 | 7.3 | 6.4 | 0.88 |
| 8 | 390 | 390 | 6.9 | 6.1 | 5.3 | 0.87 |
| 9 | 390 | 390 | 5.6 | 4.9 | 4.2 | 0.86 |
| 10 | 260 | 260 | 8.3 | 7.1 | 5.3 | 0.74 |
| 11 | 260 | 260 | 6.8 | 5.7 | 4.4 | 0.78 |
| 12 | 260 | 260 | 5.8 | 4.8 | 3.9 | 0.81 |
| 13 | 520 | 260 | 8.2 | 7.5 | 5.1 | 0.68 |
| 14 | 520 | 260 | 6.7 | 6.1 | 4.3 | 0.71 |
| 15 | 520 | 260 | 5.7 | 5.2 | 3.8 | 0.74 |

To examine the fine structure of the intermediate layer and the magnetic recording layer of the formed samples, the cross-sectional structure of each sample was observed under a high resolution transmission electron microscope. The sample was formed very thinly to avoid the observation where backward and forward crystal grains adjacent with each other were overlapped in a direction of the observation. The sample was thinned down to about 10 nm to observe the cross-sectional structure in the observation area.

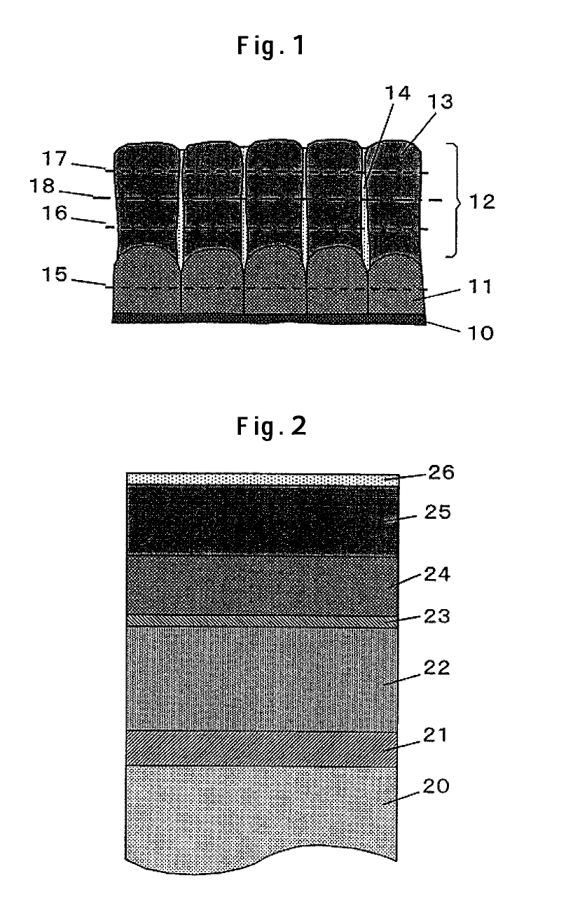

FIG. 1 shows an explanatory image of the sample 1 observed in a high resolution of about 1,250,000 magnifications. FIG. 1 also shows that the seed layer 10, the intermediate layer 11, and the magnetic recording layer 12 are laminated in this order. The oxide is observed bright in contrast, enabling the observation of how the columnar grains 13 in the magnetic recording layer are separated from each other by an oxide grain boundary layer 14 respectively. The Ru intermediate layer 11 is lower in contrast than the columnar grains 13 in the magnetic recording layer. The diameters of the grains in the Ru intermediate layer and those of the columnar grains in the magnetic recording layer were measured at the positions denoted with dotted lines in FIG. 1 for obtaining their average values from more than 10 measurement results. Concretely, the diameter of the grains in the Ru intermediate layer is measured at an intermediate position 15 in the film thickness direction; whereas, the diameter of the columnar grains in the magnetic recording layer was measured on the assumption that the columnar grains were equally divided in the film thickness direction by the parting line denoted by reference numeral 18. That is, the diameter is measured at the center 16 of the intermediate layer side portion and at the center 17 of the protective layer side portion. In the Table 1, the measured grain diameters were defined as D_Ru (nm) and D1 (nm), and D2 (nm); as parameters indicating the shapes of the columnar grains in the magnetic recording layer, the ratio of D1 to D2 was represented by D1/D2. Incidentally, samples 1 to 3 in which D2/D1 is over 1 are for this first embodiment while samples 4 to 15 in which D2/D1 is under 1 are for comparative examples.

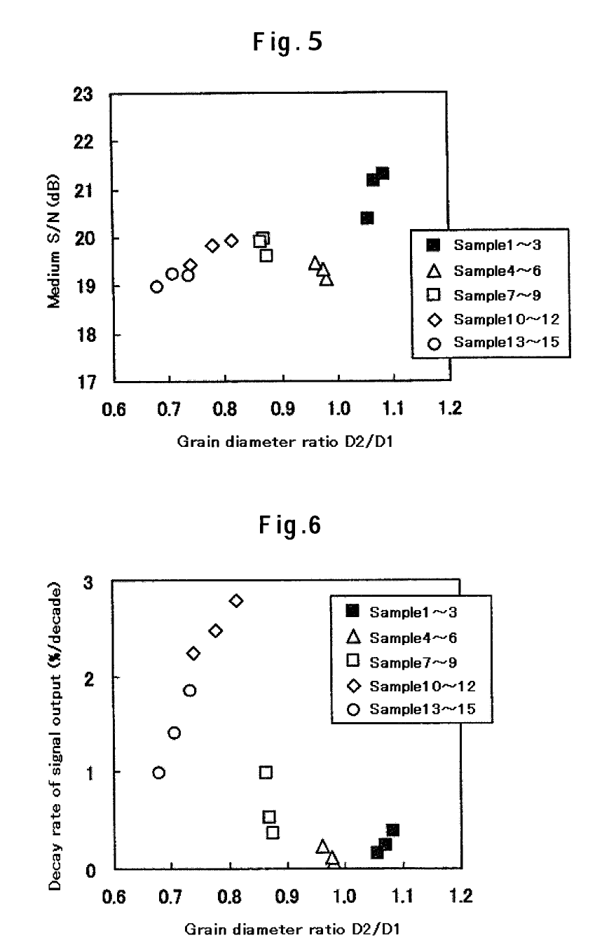

FIGS. 5 through 7 show evaluation results of the medium properties of those samples. The recording/reproducing properties were evaluated by use of a spin-stand. The head used for the evaluations is a composite magnetic head made by a reading device with use of the giant magneto-resistive effect where a shield gap length is 62 nm and a track width is 120 nm, and a single pole writing device where a track width is 150 nm. Read output and noise were measured on conditions of a circumferential speed of 10 m/s, a skew angle of 0°, and a magnetic spacing of about 15 nm. The medium S/N ratio were obtained as the ratio between the isolated waveform read output when signals having linear recording density of 1970 fr/mm is recorded and the integral noise when signals having linear recording density of 23620 fr/mm is recorded.

The resistance to thermal decay is evaluated by measuring the changes of the read output measured for 1 to 3000 seconds taking as the criterion the read output obtained when about one second passed after a signal of 3940 fr/mm linear recording density is recorded, and subjecting them for evaluation with a declination obtained by plotting the change rate with a time logarithm. Hereinafter, the resistance to thermal decay will be referred to as an output decay rate.

The medium surface smoothness is evaluated by a head flying test where the glide head with a piezo element is flown from the outer periphery to the inner periphery of the medium, and the average value of the piezo element outputs at that time is obtained as an index. Hereinafter, the average value will be referred to as a glide head average output. Although the head flyability is also degraded by stuck dust and abnormal growth of crystal, the maximum output of the piezo element increases in such a case while the average output is not affected so much by that. Instead, when the surface of the medium becomes rough, it affects the head flying stability, adversely increasing the average output value even if the roughness is only microscopic.

FIG. 5 shows a graph for describing how the medium S/N ratio depends on the diameter ratio D2/D1 of the columnar grains in the magnetic recording layer. In case of a sample having a conventional shape of grains in the comparative example, the medium S/N ratio becomes the maximum between 0.8 and 0.9 of the diameter ratio D2/D1. It is thus considered that the shape of the grains is slightly tapered and the S/N ratio is improved when the grain boundary layers are formed by controlling such processes as a sputtering rate. On the contrary, in case of the sample in this embodiment, in which the diameter ratio D2/D1 is over 1, the medium S/N ratio is higher than that of the sample in the comparative example.

FIG. 6 shows a graph for describing an output decay rate. The sample in the comparative example, which is composed of tapered grains having a grain diameter ratio D2/D1 of 0.85 or lower, was found to be high in output decay rate and insufficient in resistance to thermal decay. On the other hand, the sample which is composed of the grains whose grain diameter ratio D2/D1 is over 0.9, which also includes samples of this embodiment, was found to be low in output decay rate and have strong resistance to thermal decay.

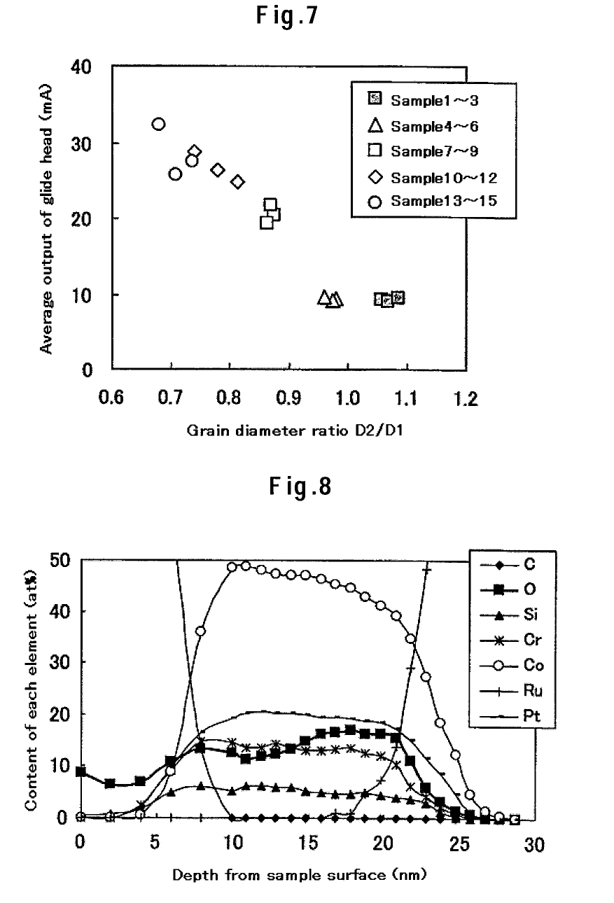

FIG. 7 shows a graph for describing glide head outputs. As shown in FIG. 7, the head flyability significantly depends on the shape of crystal grains in the magnetic recording layer. If the diameter ratio D2/D1 of the grains is low and the grains in the protective layer side portion is more tapered, the glide head average output increases, making it difficult to fly the head stably. On the other hand, the samples composed of the grains whose diameter ratio D2/D1 is 0.9 or over, which also includes the samples in this embodiment, are small in glide head average output. The head flyability thus becomes favorable.

According to the results, the sample in this embodiment is found to be favorable in all the aspects of the medium S/N ratio, resistance to thermal decay, and head flyability. The reasons why the medium S/N ratio is so high are that the head flies stably and the center of gravity of grains is shifted slightly toward the protective layer since the shape of the grains is clavate, the spacing between grains is substantially reduced to obtain larger outputs, and sharper bit boundaries are formed. In addition to those reasons, it is also considered that information is efficiently recorded since the exchange coupling differs between upper grains and between lower grains. Regarding the granular-structured magnetic recording layer, considering any of those reasons, it was found that if the diameter of the columnar grains in the protective layer side portion is larger than that of the columnar grains in the intermediate layer side portion, the medium properties are better.

The effects obtained by the shape of the grains in the magnetic recording layer are particularly shown when the magnetic recording layer has a granular structure, and not shown when the magnetic recording layer is made of a Co—Cr—Pt-alloy that has a property of lowering the exchange coupling between magnetic crystal grains by use of a Cr segregated structure. If the Co—Cr—Pt-alloy of Cr segregated structure is used for the magnetic recording layer, the diameter of grains in the protective layer side portion is larger than that of the grains in the intermediate layer side portion, which shape is seen on many media and similar to that of the grains of the present invention. In that case, however, grains are sorted during the formation of the grains and thereby such shapes of the grains are formed. Some grains are thus extremely tapered in shape and others are shaped as if they stopped growing halfway. Their shape therefore is different from those of the grains in the magnetic recording layer of the present invention. In case of the Co—Cr—Pt-alloy having such a Cr segregation structure, many fine grains exist in the intermediate layer side portion of the magnetic recording layer, so that the grains are rather small in width and the exchange coupling between magnetic grains is strong. This hinders noise reduction. On the other hand, because in the present invention the shape of grains is controlled by changing the width of the grain boundary layers, there are no fine grains that are weak in resistance to thermal decay nor grains strong in exchange coupling between magnetic grains in the intermediate layer side portion of the magnetic recording layer. This is why the grains do not adversely affect the resistance to thermal decay and the noise characteristic adversely. Accordingly, to obtain the effect of the present invention, it is important to control the shape of the columnar grains in the granular-structured magnetic recording layer depending on the width of the grain boundary layers.

Furthermore, even if the magnetic recording layer has the granular structure, each of the grains in the magnetic recording layer need to be a shape of a continuous column between the boundaries of the intermediate layer and of the protective layer. For example, if the process is stopped halfway to laminate different composition layers of the magnetic recording layer, the grains in the magnetic recording layer are separated from each other and laminated in the film thickness direction. This is because the oxide grows to enclose respective metallic grains. In such a case, a high medium S/N ratio and high resistance to thermal decay are not obtained. For example, in the process for forming the sample of the magnetic recording layer, which is manufactured just like the case of the sample 1 in this embodiment, if the power supply is turned off once before the supply voltage is changed, the medium S/N ratio becomes 19.1 dB and the output decay rate becomes 5.9%/digit. Accordingly, in order to obtain the effect of the present invention by controlling the structure of the grains in the magnetic recording layer, the sputtering process for forming the magnetic recording layer needs to be comprised of at least two consecutive steps. If the oxygen content in the intermediate layer side portion of the magnetic recording layer is set to be high, the grains are excessively fine, so that plural grains in the magnetic recording layer come to be formed on one grain in the intermediate layer, resulted in that each of the grains in the magnetic recording layer does not grow as a continuous columnar grain between the boundaries of the intermediate layer and of the protective layer. To cope with this, it is important that the oxygen content in the magnetic recording layer is adjusted. Otherwise, it is effective that the intermediate layer located immediately beneath the magnetic recording layer is formed of Ru or an Ru alloy and that the magnetic recording layer is subjected to epitaxial growth on the intermediate layer.

Those samples were subjected to the composition analysis in a depth direction under an x-ray photoelectron spectroscopy. Each sample was subjected to a sputtering in a depth direction from the sample surface with the use of an ion gun having an acceleration voltage of 500V to make a hole. Analysis was made for the composition within a range of a length of 1.5 mm and a width of 0.1 mm with an aluminum Kα ray used as an x-ray source. The content (at %) of each element in each sample is found by detecting the spectrum around an energy corresponding to each of the 1s electron of C, the 1s electron of O, the 2s electron of Si, the 2P electron of Cr, the 2p electron of Co, the 3d electron of Ru, and the 4f electron of Pt.

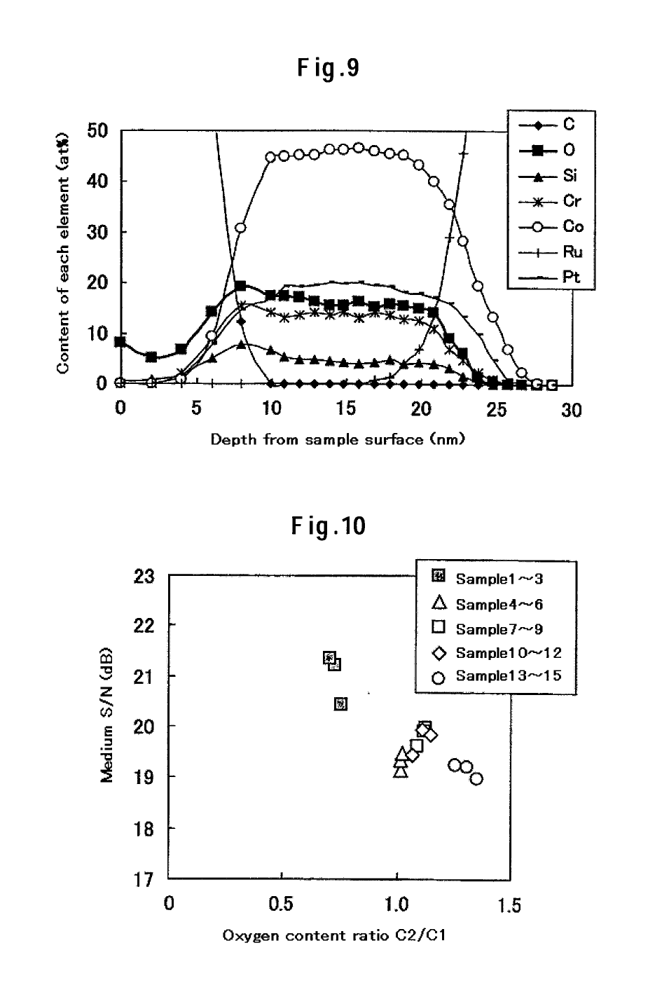

FIGS. 8 and 9 show a plotting result of the content of each element in a depth direction from the surface of the sample. FIG. 8 shows a plotting result of the sample 1 in this embodiment while FIG. 9 shows a plotting result of the sample 10 in a comparative example. Herein, noticeable is the distribution of the oxygen content in the magnetic recording layer. The magnetic recording layer, which is almost located in the area in the depth direction, mainly has Co. In this embodiment shown in FIG. 8, the oxygen content increases toward the upper right, or the oxygen content is higher in the intermediate layer side portion of the magnetic recording layer. On the other hand, in the comparative example shown in FIG. 9, the oxygen content decreases slightly toward the lower right, or the oxygen content in the intermediate layer side portion of the magnetic recording layer is lower.

In order to compare the distribution of the oxygen content in the magnetic recording layer with another quantitatively, the magnetic recording layer was made to be an area in which the C content is under 5 at % and the Ru content is under 10 at %, and further an assumption was made where the magnetic recording layer is divided equally into an intermediate layer side portion and a protective layer side portion at its center as a boundary. The average values C1 and C2 of the oxygen contents of those divided portions are obtained to thereby calculate the oxygen content ratio C2/C1. FIG. 10 shows a plotting result of the medium S/N ratio with respect to the oxygen content ratio C2/C1. The plotting result showed that when the oxygen content ratio C2/C1 is under 1, the medium S/N ratio is favorable. In other words, in the granular-structured magnetic recording layer, if the oxygen content in the protective layer side portion is lower than that in the intermediate layer side portion, the medium S/N ratio which is higher is obtained.

When the results of this embodiment are examined from the viewpoint of the manufacturing processes of the perpendicular magnetic recording medium, the process for forming the magnetic recording layer has a characteristic as denoted in Table 1. In other words, the effect of the present invention was obtained by the magnetic recording layer sputtering process configured by two consecutive steps and by the power supply in the first step, which is set to be lower than that in the second step. The effect of the present invention is not obtained if the same power is supplied in both first and second steps or if the power supply in the first step is set higher than that in the second step.

### Second Embodiment

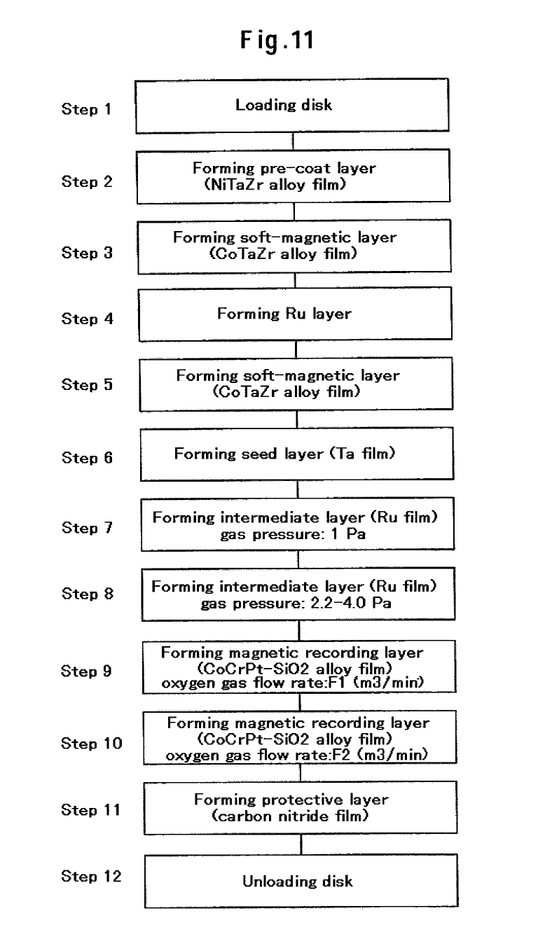

The perpendicular magnetic recording medium in this second embodiment was manufactured in the same layer configuration and under the same process conditions as those of the first embodiment. On the other hand, the target and process for forming the magnetic recording layer are different between the first and second embodiments. FIG. 11 shows a flowchart of how to manufacture the perpendicular magnetic recording medium. The target was used in which 6 mol % silicon oxide is added to a Co base alloy with 13 at % Cr and 16 at % Pt. The power supply was to be fixed at 260 W in all the processes. The partial pressure of oxygen in the sputtering gas was to be changed during the process to thereby change the fine structure of the magnetic recording layer. The flow rate of the oxygen gas contained therein was to be changed to thereby control the partial pressure of oxygen with the total gas flow rate being fixed at 2×10⁻⁴ m³/min so as to hold the gas pressure at 2.2 Pa. With use of units of the oxygen gas flow rate in the first half of the process: F1 (m³/min) and that in the second half of the process: F2 (m³/min), Table 2 shows the forming conditions for each sample. The process time was adjusted to obtain a thickness of 13.4 nm for the magnetic recording layer.

TABLE 2

| | | | Ru Layer | Magnetic | | |
|---|---|---|---|---|---|---|
| | Magnetic Recording | | Grain | Recording Layer Grain | | |
| | Layer Process | | Diameter | Diameter | | |
| Sample No. | F1 (m³/min) | F2 (m³/min) | D_Ru (nm) | D1 (nm) | D2 (nm) | D2/D1 |
| 16 | 2.0E−06 | 8.0E−07 | 6.6 | 5.5 | 5.8 | 1.05 |
| 17 | 2.0E−06 | 1.0E−06 | 6.7 | 5.6 | 5.8 | 1.04 |
| 18 | 2.0E−06 | 1.5E−06 | 6.8 | 5.7 | 5.8 | 1.02 |
| 19 | 2.0E−06 | 2.0E−06 | 6.7 | 5.6 | 4.9 | 0.88 |
| 20 | 2.0E−06 | 2.5E−06 | 6.8 | 5.7 | 4.3 | 0.76 |
| 21 | 2.0E−06 | 3.0E−06 | 6.6 | 5.5 | 3.8 | 0.70 |
| 22 | 1.5E−06 | 8.0E−07 | 6.5 | 5.5 | 5.7 | 1.04 |
| 23 | 1.5E−06 | 1.0E−06 | 6.6 | 5.6 | 5.7 | 1.02 |
| 24 | 1.5E−06 | 1.2E−06 | 6.5 | 5.5 | 5.6 | 1.01 |
| 25 | 1.5E−06 | 1.5E−06 | 6.4 | 5.4 | 5.1 | 0.94 |
| 26 | 1.5E−06 | 2.0E−06 | 6.6 | 5.6 | 4.6 | 0.82 |
| 27 | 1.5E−06 | 2.5E−06 | 6.5 | 5.5 | 4.1 | 0.75 |

Similarly to the first embodiment, the diameters of the grains in the Ru intermediate layer and the columnar grains in the magnetic recording layer were obtained by observing the cross sectional structures of those layers under the high resolution transmission electron microscope, the results of which are shown in Table 2. This second embodiment adopts samples 16 to 18 as well as samples 22 to 24. In the samples 16 to 18 and 22 to 24, the parameter D2/D1 that denotes the shape of the columnar grains in the magnetic recording layer is over 1. The comparative example adopts samples 19 to 21 and samples 25 to 27. In the samples 19 to 21 and 25 to 27, the D2/D1 value is under 1.

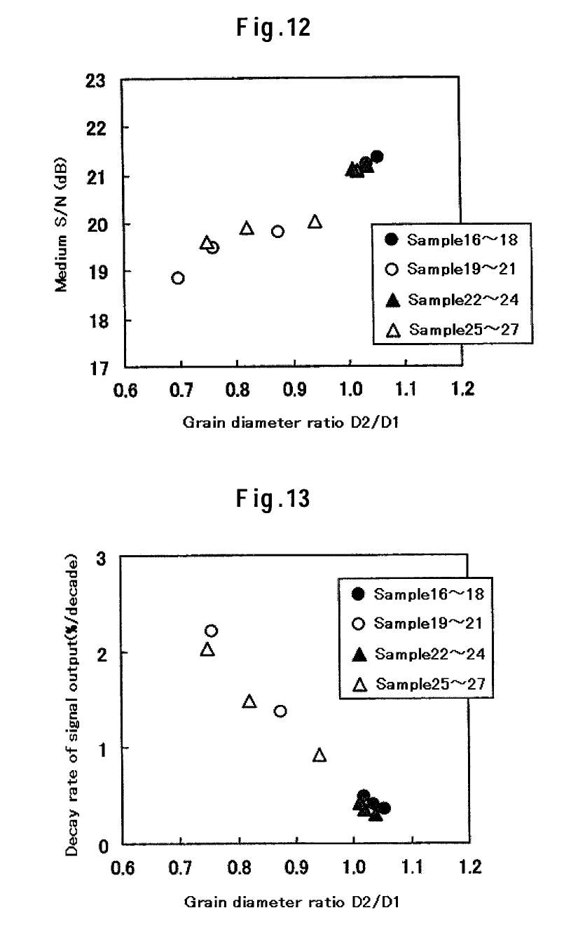

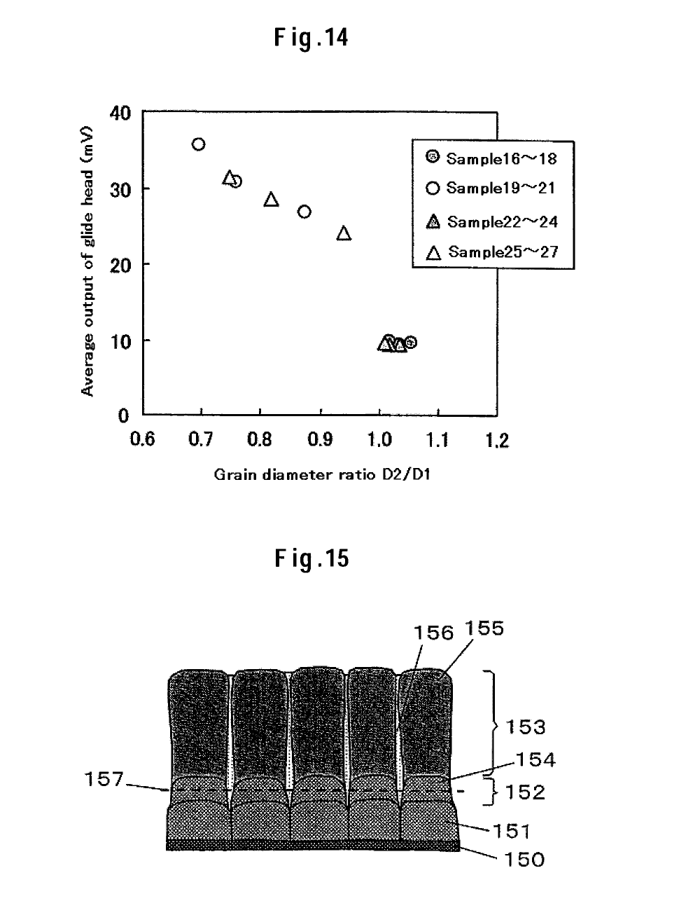

FIGS. 12 through 14 show the evaluation results of the medium properties of those samples. The evaluation method is the same as that in the first embodiment. In case of the samples in this second embodiment, in which the diameter ratio D2/D1 of the columnar grains in the magnetic recording layer is over 1, the medium S/N ratio is high, the output decay rate is low, and the glide head average output is low. Those properties are thus better than those of the samples in the comparative example.

As shown in Table 2, the effect of the present invention is obtained only with the magnetic recording layer sputtering process configured by two different steps in which the oxygen gas flow rate in the first step is set to be higher than that in the second step. If the same gas flow rate is constantly employed in those two steps or the oxygen gas flow rate in the first step is set to be lower than that in the second step, the effect of the present invention is not obtained.

### Third Embodiment

The perpendicular magnetic recording medium in this third embodiment was manufactured in the same layer configuration and on the same process conditions as those of the first embodiment. However, the processes for forming the intermediate layer and the magnetic recording layer are different between the first and third embodiments. Used in this embodiment was the intermediate layer which is formed by laminating a 4 nm thick granular-structured Ru alloy metallic film on a 6 nm thick Ru film. As for the Ru film forming process, the process was made by sequentially laminating a film formed under a sputtering process at a gas pressure of 1 Pa and a film formed under a sputtering process at a gas pressure of 2.2 Pa to 4.0 Pa. The film thickness ratio between those two Ru films and the gas pressure for forming the second Ru layer were changed to thereby change the size of the Ru grains. As for the granular-structured Ru metallic film, a Ru—SiO₂ film or Ru—Ta₂O₅ film were subjected to its formation. In order to make a comparison, another sample is also manufactured in which the Ru alloy film is replaced with a Ru film to which no oxide is added. The Ru—SiO₂ film and the Ru—Ta₂O₅ film was formed under a sputtering process at a gas pressure of 2.2 Pa with use of a target obtained by adding Si oxide of 5 mol % to 14 mol % or Ta oxide to Ru.

A magnetic recording layer was formed immediately on this granular-structured Ru alloy film by sputtering in argon and oxygen mixed gas with the use of a target obtained by adding 8 mol % Si oxide or Ta oxide to a Co base alloy with 12 at % Cr and 21 at % Pt. In that process, the gas pressure is 2.2 Pa, the partial pressure of oxygen is 0.02 Pa, and the power supply is 260 W; those values were all fixed. In other words, no conditions were changed in the processes; all those processes were included in a simple step. The magnetic recording layer was to be formed at a thickness of 14.2 nm.

Just like in the first embodiment, observation was made for the cross sectional structure of each sample under the high resolution electron microscope. FIG. 15 shows an explanatory image of a sample 30 observed in a high resolution of about 1,250,000 magnifications. The observed image clearly shows that a seed layer 150, an Ru intermediate layer 151, an Ru alloy intermediate layer 152, and a magnetic recording layer 153 are laminated in this order. The image also shows how the Ru grains 154 in the Ru alloy intermediate layer and the columnar grains 155 in the magnetic recording layer are separated from each other by oxide grain boundary layers 156 to be transformed into granular-structured ones. Table 3 shows the diameter of a grain of each sample, obtained through the observation of such a cross sectional structure. The diameter of the Ru grains in the granular-structured Ru alloy intermediate layer was measured at a position 157 denoted with a dotted line in FIG. 15, then averaged from more than 10 measured sizes. The distance between the center of an Ru grain and the center of its adjacent Ru grain is referred to as grain spacing, which is represented as L_Ru. The diameter of the columnar grains in the magnetic recording layer is found as an average value of the diameter D1 of those in the intermediate layer side portion and the diameter D2 of those in the protective layer side portion and represented as D_CCP. Table 3 also shows the diameter ratio D_CCP\D_Ru between the diameter of the Ru grains in the granular-structured intermediate layer located immediately beneath the magnetic recording layer and the diameter of the columnar grains in the magnetic recording layer. This third embodiment uses samples 28 to 32, as well as samples 36 to 37 in which the value of this ratio is over 1 respectively. The comparative example uses samples 33 to 35, as well as samples 38 to 40 in which the ratio value is under 1.

TABLE 3

| | | Ry Alloy Layer Grain | | Magnetic Recording Layer Grain | | |
|---|---|---|---|---|---|---|
| Sample | | Diameter | | Diameter | | |
| No. | Additive to Ru | L_Ru (nm) | D_Ru (nm) | D1 (nm) | D2 (nm) | D_CCP/D_Ru |
| 28 | SiO₂ | 9.2 | 8 | 7.9 | 8.5 | 1.03 |
| 29 | SiO₂ | 6 | 4.7 | 4.7 | 5.3 | 1.06 |
| 30 | SiO₂ | 7.1 | 5.8 | 5.8 | 6.3 | 1.04 |
| 31 | SiO₂ | 8.7 | 7.6 | 7.4 | 8 | 1.01 |
| 32 | SiO₂ | 7 | 5.9 | 5.9 | 6.2 | 1.03 |
| 33 | SiO₂ | 7.2 | 6.4 | 6.4 | 6.4 | 1.00 |
| 34 | SiO₂ | 7.2 | 6.6 | 6.6 | 6.4 | 0.98 |
| 35 | Non | 7.1 | 7.1 | 6.5 | 5.67 | 0.86 |
| 36 | Ta₂O₅ | 6.5 | 5.2 | 5.2 | 5.7 | 1.05 |
| 37 | Ta₂O₅ | 6.6 | 5.5 | 5.5 | 5.8 | 1.03 |
| 38 | Ta₂O₅ | 6.6 | 5.8 | 5.8 | 5.8 | 1.00 |
| 39 | Ta₂O₅ | 6.5 | 5.9 | 5.9 | 5.7 | 0.98 |
| 40 | Non | 6.5 | 6.5 | 5.9 | 5.13 | 0.85 |

As shown with the results in FIG. 15 and Table 3, even where the process for forming the magnetic recording layer is configured by one simple step, if an additive is added to the Ru intermediate layer located immediately beneath the magnetic recording layer to make it as a granular-structured one and the diameter of the Ru grains is set to be smaller than that of the columnar grains in the magnetic recording layer, the shape of the columnar grains in the magnetic recording layer was not tapered; it was clavate from the intermediate layer toward the protective layer.

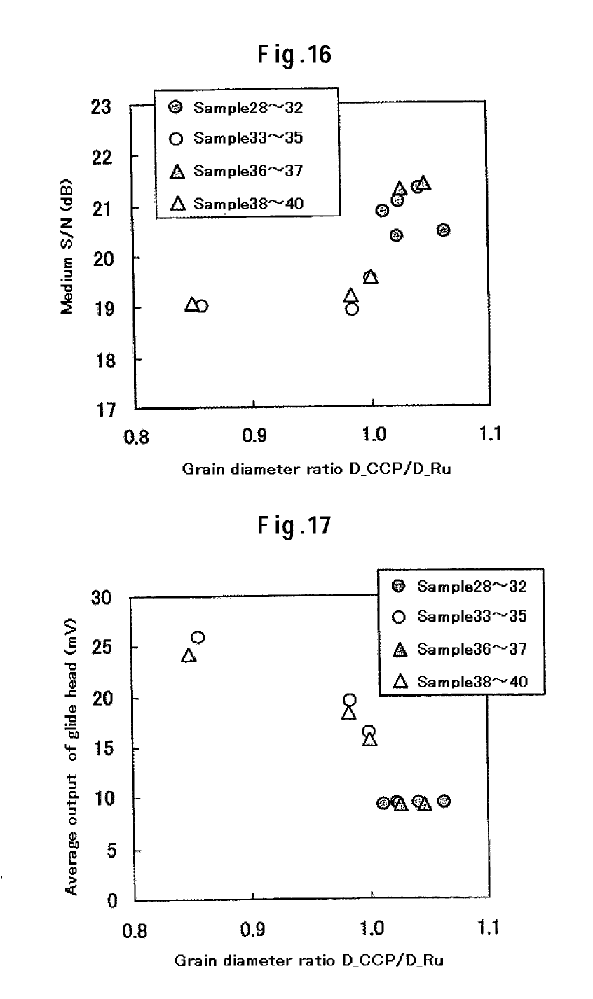

FIGS. 16 and 17 show evaluation results of the medium properties of those samples. The evaluation method is the same as that in the first embodiment. FIG. 16 shows the medium S/N ratio and FIG. 17 shows an average output of the glide head. If the diameter ratio D_CCP/D_Ru between the diameter of the Ru grains in the granular-structured intermediate layer and the diameter of the columnar grains in the magnetic recording layer is over 1, the medium S/N ratio is high and the glide head average output is low. The medium properties are thus proved to be excellent. In other words, in case of the perpendicular magnetic recording medium having a granular-structured magnetic recording layer, the intermediate layer located immediately beneath the magnetic recording layer has a granular structure; and if the diameter of the columnar grains in the magnetic recording layer is larger than that of the grains in the intermediate layer located immediately beneath the magnetic recording layer, the medium properties are proved to be excellent.

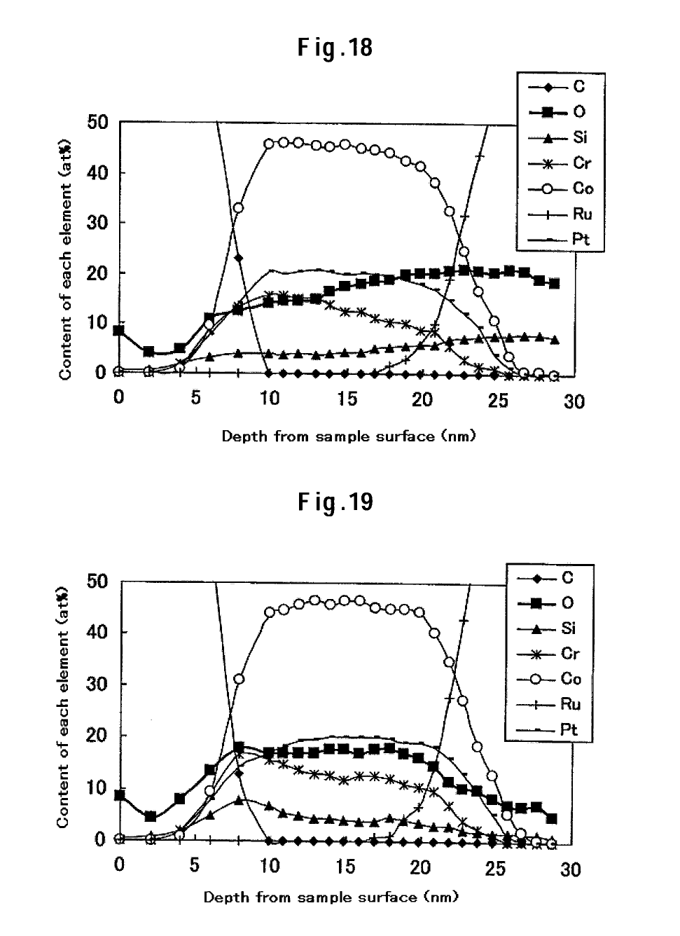

Next, a description will be made for composition analysis of each sample performed in the depth direction with the use of an x-ray photoelectron spectroscopy. The analyzing method is the same as that in the first embodiment. FIGS. 18 and 19 show plotting results of the content of each element in the depth direction from the surface of each sample. FIG. 18 shows a plotting result of the sample 30 in this third embodiment and FIG. 19 shows a plotting result of the sample 33 in the comparative example. Herein noticeable is the distribution of the oxygen content in the magnetic recording layer. The magnetic recording layer forms almost all area in a depth direction where Co is mainly contained. In this third embodiment shown in FIG. 18, the oxygen content rises toward the upper right and the intermediate layer side portion of the magnetic recording layer is shown higher. The oxygen content further increases within the area in a depth direction of the intermediate layer. On the other hand, in the comparative example shown in FIG. 19, the oxygen content is distributed almost evenly in the whole magnetic recording layer and the oxygen content in the intermediate layer side portion is lower than that in the magnetic recording layer.

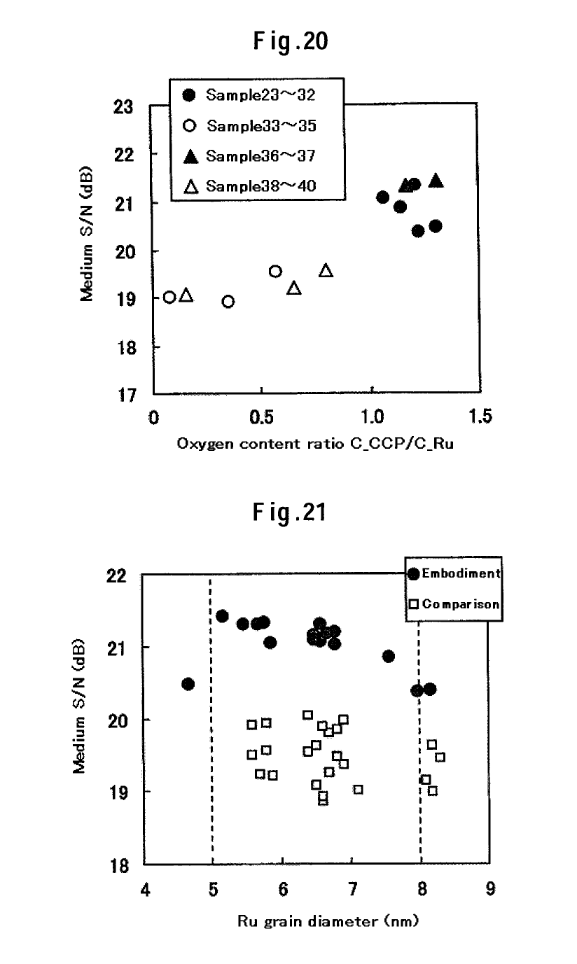

In order to make the comparison between oxygen contents in the magnetic recording layer and that in the intermediate layer, the oxygen content ratio between those layers was to be obtained just like in the first embodiment. Specifically, assuming that the magnetic recording layer is an area in which the C content is under 5 at % and the Ru content is under 10 at %, the average value C_CCP of the measured oxygen contents was obtained. Then, assuming that the Ru intermediate layer is an area in which the Ru content is higher than the contents of other elements and that the granular-structured intermediate layer located immediately beneath the magnetic recording layer is an area of 4 nm away from the magnetic recording layer side boundary, the average value C_Ru of the measured oxygen contents in the Ru intermediate layer was obtained. Then, the oxygen content ratio C_CCP\C_Ru was calculated. FIG. 20 shows a plotting result of the medium S/N ratio with respect to the oxygen content ratio C_CCP\C_Ru. FIG. 20 reveals that the medium S/N ratio is favorable when the oxygen content ratio C_CCP\C_Ru is under 1. In other words, as for the perpendicular magnetic recording medium having a granular structured magnetic recording layer, the medium S/N ratio is higher where the intermediate layer located immediately beneath the magnetic recording layer has a granular structure and the oxygen content in the magnetic recording layer is lower than that in the intermediate layer located immediately beneath the magnetic recording layer.

Considering that the effect of the shape of the grains in the magnetic recording layer depends significantly on the diameter of the grains in the intermediate layer located immediately beneath the magnetic recording layer, the present inventors examined a relationship between the diameter of the Ru grains in the intermediate layer located immediately beneath the magnetic recording layer and the medium S/N ratio. FIG. 21 shows a relationship between the diameter of the Ru grains and the medium S/N ratio. Although it is apparent that there is a difference between samples in this third embodiment and in the comparative example, the medium S/N ratio is high even in some samples in this third embodiment in which the diameter of the Ru grains is 5 nm to 8 nm. The change of the average diameter of the columnar grains in the magnetic recording layer depends on the diameter of the Ru grains, and the effect of the present invention is expected to be significant by properly selecting the aspect ratio and cubic volume of the columnar grains of the magnetic recording layer.

Regarding the sample medium described in an embodiment, dust was charged between the head and the medium, and the disk was rotated contrariwise to be subjected to the test of the durability. The durability was found to be in proportion to the head flyability. In other words, according to the present invention, the sample in which the head flyability is improved in advance has almost no minute scratches on its surface after the dust injection test. This showed that the sample is resistant to peeling-off. On the other hand, in samples in the comparative example, in which the columnar grains in the magnetic recording layer is tapered, many scratches were recognized on the surface and the surface film was peeled off after a dust injection test. The sample was thus concluded to be very weak in the resistance to peeling-off.

After that, the anticorrosion test was performed for each of those samples. Each sample was left over under high temperature and high humidity conditions for three days, then checked for corrosion points on the sample surface. In case of a sample for which the head flyability is improved in advance according to the present invention, almost no corrosion point was recognized and thus the sample was proved to have enough corrosion resistance. On the other hand, in samples in the comparative example, many corrosion points were observed on the sample surface. It was thus concluded that the sample is weak in the resistance to corrosion. In addition, a new sample was manufactured by thinning the protective layer of each of the samples of the inventive and comparative examples down to 2.5 nm for a corrosion resistance test. While in the comparative example, the number of corrosion points further increased on the surface of each sample, in the inventive example, the number of corrosion points on the surface of each sample did not increase, in which the corrosion resistance was found to be consistently favorable. According to the present invention, both head flyability and corrosion resistance of the perpendicular magnetic recording medium are improved, and the high medium reliability is obtained.

According to the present invention, the medium S/N ratio is improved while both head flyability and durability of the perpendicular magnetic recording medium are secured, so that the perpendicular magnetic recording medium can assure high density recording, long-term durability, and high reliability. The magnetic recording media manufactured as described above, which assures high density recording, can be applied to, e.g., the compact and yet large capacity magnetic disk drives.

It is to be understood that the above description is intended to be illustrative and not restrictive. Many embodiments will be apparent to those of skill in the art upon reviewing the above description. The scope of the invention should, therefore, be determined not with reference to the above description, but instead should be determined with reference to the appended claims alone with their full scope of equivalents.

1-20. (canceled)

21. A perpendicular magnetic recording medium comprising a substrate, and arranged in order thereon, at least a soft magnetic layer, an intermediate layer, a magnetic recording layer, and a protective layer,
wherein the magnetic recording layer has a granular structure composed of a multiplicity of columnar grains and an oxide-containing grain boundary layer, wherein the granular structure is in columnar form in which the columnar grains continuously extend from an interface with the intermediate layer to another interface with the protective layer, and wherein the columnar grains have such shapes that, assuming that the columnar grains are each divided equally into two portions in a film thickness direction thereof, one portion adjacent to the protective layer is larger in diameter than the other portion adjacent to the intermediate layer.

22. The perpendicular magnetic recording medium according to claim 21, wherein the magnetic recording layer has such an oxygen content distribution that, assuming that the magnetic recording layer is equally divided into two portions in a film thickness direction thereof, one portion adjacent to the protective layer is lower in oxygen content than the other portion adjacent to the intermediate portion.

23. The perpendicular magnetic recording medium according to claim 21, wherein the intermediate layer includes two or more layers, and wherein, among the two or more intermediate layers, an intermediate layer which is located immediately beneath the magnetic recording layer comprises ruthenium (Ru).

24. The perpendicular magnetic recording medium according to claim 21, wherein the intermediate layer includes two or more layers, and wherein, among the two or more layers, a layer which is located immediately beneath the magnetic recording layer has a granular structure composed of a multiplicity of grains and an oxide-containing grain boundary layer, wherein the columnar grains constituting the magnetic recording layer have diameters larger than diameters of the grains constituting the layer located immediately beneath the magnetic recording layer, and wherein the diameters of the columnar grains constituting the magnetic recording layer are each the average of a diameter of the portion adjacent to the protective layer and a diameter of the portion adjacent to the intermediate layer.

25. The perpendicular magnetic recording medium according to claim 24, wherein the magnetic recording layer is lower in oxygen content than the intermediate layer located immediately beneath the magnetic recording layer.

26. The perpendicular magnetic recording medium according to claim 24, wherein the multiplicity of grains constituting the intermediate layer located immediately beneath the magnetic recording layer comprise ruthenium (Ru).

27. The perpendicular magnetic recording medium according to claim 26, wherein the grains constituting the intermediate layer located immediately beneath the magnetic recording layer have diameters of 5 nm or more and less than 8 nm.

28. A magnetic recording/reproducing apparatus, comprising:
a magnetic recording medium,
a medium driving unit that drives the magnetic recording medium,
a magnetic head that carries out reading/writing of information from/to the magnetic recording medium, and
a magnetic head access unit that allows the magnetic head to access toward the magnetic recording medium,
wherein the magnetic recording medium is a perpendicular magnetic recording medium including a substrate, and arranged in order thereon, at least a soft magnetic layer, an intermediate layer, a magnetic recording layer, and a protective layer, wherein the magnetic recording layer has a granular structure composed of a multiplicity of columnar grains and an oxide-containing grain boundary layer, wherein the granular structure is in columnar form in which the columnar grains continuously extend from an interface with the intermediate layer to another interface with the protective layer, and wherein the columnar grains have such shapes that, assuming that the columnar grains are each divided equally into two portions in a film thickness direction thereof, one portion adjacent to the protective layer is larger in diameter than the other portion adjacent to the intermediate layer.

29. The magnetic recording/reproducing apparatus according to claim 28, wherein the intermediate layer includes two or more layers, and wherein, among the two or more layers of the intermediate layer, a layer which is located immediately beneath the magnetic recording layer has a granular structure composed of a multiplicity of grains and an oxide-containing grain boundary layer, wherein the columnar grains constituting the magnetic recording layer have diameters larger than diameters of the grains constituting the layer located immediately beneath the magnetic recording layer, and wherein the diameters of the columnar grains constituting the magnetic recording layer are each the average of a diameter of the portion adjacent to the protective layer and a diameter of the portion adjacent to the intermediate layer.

30. A method for manufacturing a perpendicular magnetic recording medium including a substrate, and arranged in order thereon, at least a soft magnetic layer, an intermediate layer, a magnetic recording layer, and a protective layer, the magnetic recording layer having a granular structure composed of a multiplicity of columnar grains and an oxide-containing grain boundary layer, the granular structure being in columnar form, the columnar grains continuously extending from an interface with the intermediate layer to another interface with the protective layer, and the columnar grains having such shapes that, assuming that the columnar grains is each divided equally into two portions in a film thickness direction thereof, one portion adjacent to the protective layer is larger in diameter than the other portion adjacent to the intermediate layer, the method comprising:
forming the magnetic recording layer through a sputtering process including at least two consecutive steps of a first step and a second step, wherein a power supply in sputtering in the first step is lower than a power supply in sputtering in the second step.

31. A method for manufacturing a perpendicular magnetic recording medium including a substrate, and arranged in order thereon, at least a soft magnetic layer, an intermediate layer, a magnetic recording layer, and a protective layer, the magnetic recording layer having a granular structure composed of a multiplicity of columnar grains and an oxide-containing grain boundary layer, the granular structure being in columnar form, the columnar grains continuously extending from an interface with the intermediate layer to another interface with the protective layer, and the columnar grains having such shapes that, assuming that the columnar grains is each divided equally into two portions in a film thickness direction thereof, one portion adjacent to the protective layer is larger in diameter than the other portion adjacent to the intermediate layer, the method comprising:
forming the magnetic recording layer through a sputtering process including at least two consecutive steps of a first step and a second step, wherein an oxygen gas flow rate in the first step is higher than an oxygen gas flow rate in the second step.

32. A method for manufacturing a perpendicular magnetic recording medium, the method comprising the steps of:
forming a soft magnetic layer on a substrate;
forming an intermediate layer on the soft magnetic layer;
forming a magnetic recording layer on the intermediate layer, the magnetic recording layer having a granular structure composed of a multiplicity of columnar grains and an oxide-containing grain boundary layer, the granular structure being in columnar form, where the columnar grains continuously extending from an interface with the intermediate layer through the magnetic recording layer, and the columnar grains having such shapes that, assuming that the columnar grains are each divided equally into two portions in a film thickness direction thereof, one portion adjacent to the protective layer is larger in diameter than the other portion adjacent to the intermediate layer,
wherein the step of forming the magnetic recording layer comprises:
the first step of forming a first layer of the magnetic recording layer through a sputtering process in which a power P1 is supplied; and
the second step of forming a second layer of the magnetic recording layer through another sputtering process in which a power P2 continuously increased from the power P1 is supplied.

33. The method for manufacturing a perpendicular magnetic recording medium, according to claim 32, wherein the magnetic recording layer is so formed that an oxygen content in the second layer of the magnetic recording layer is lower than an oxygen content in the first layer of the magnetic recording layer.

34. A method for manufacturing a perpendicular magnetic recording medium, the method comprising the steps of:
forming a soft magnetic layer on a substrate;
forming an intermediate layer on the soft magnetic layer;
forming a magnetic recording layer on the intermediate layer, the magnetic recording layer having a granular structure composed of a multiplicity of columnar grains and an oxide-containing grain boundary layer, the granular structure being in columnar form where the columnar grains continuously extending from an interface with the intermediate layer through the magnetic recording layer, and the columnar grains having such shapes that, assuming that the columnar grains are each divided equally into two portions in a film thickness direction thereof, one portion adjacent to the protective layer is larger in diameter than the other portion adjacent to the intermediate layer,
wherein the step of forming the magnetic recording layer comprises:
the first step of forming a first layer of the magnetic recording layer through a sputtering process in which an oxygen gas flow rate in a process gas is F1; and
the second step of forming a second layer of the magnetic recording layer through another sputtering process in which an oxygen gas flow rate in the process gas is F2 that is continuously decreased from the oxygen gas flow rate F1.

35. The method for manufacturing a perpendicular magnetic recording medium, according to claim 34, wherein the magnetic recording layer is so formed that the second layer is lower in oxygen content than the first layer.
